(19) United States
(12) Patent Application Publication
(10) Pub. No.: US 2007/0196997 A1
(43) Pub. Date: Aug. 23, 2007

(54) METHOD OF FORMING ISOLATION STRUCTURE OF SEMICONDUCTOR DEVICE

(75) Inventors: Sang Deok Kim, Seoul (KR); Bo Min Park, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/616,020

(22) Filed: Dec. 26, 2006

(30) Foreign Application Priority Data
Feb. 23, 2006 (KR) 2006-17723

(51) Int. Cl. H01L 21/76

(52) U.S. Cl. 438/424

(57) ABSTRACT

A method for forming an isolation structure of a semiconductor device includes forming an isolation trench on a semiconductor substrate. A first insulating layer is formed over the isolation trench and the substrate. A spin-on-dielectric (SOD) insulating layer is formed over the first insulation layer, the SOD insulating layer filling the isolation trench and extending above an upper level of the isolation trench. The SOD insulating layer provided within the isolation trench is removed to expose an upper portion of the isolation trench, wherein a lower portion of the isolation trench remains filled with the SOD insulating layer. A second insulating layer is formed over the SOD insulating layer that is filling the lower portion of the isolation trench, wherein the second insulating layer fills the upper portion of the isolation trench.

### CROSS-REFERENCES TO RELATED APPLICATIONS

The present application claims priority to Korean patent application number 10-2006-17723, filed on Feb. 23, 2006, which is incorporated by reference in its entirety.

### BACKGROUND OF THE INVENTION

The present invention relates to a method of forming an isolation structure of a semiconductor device, and more particularly, to a method which can enhance the gap fill margin of a trench for an isolation structure.

In general, a semiconductor device contains an isolation area for electrically isolating the individual circuit patterns. Since the size of the active area and the process margin of the succeeding processes depend on the isolation area formed in an initial step, as the semiconductor device becomes more high-integrated and miniaturized, studies have been actively conducted for reducing the size of the isolation region.

As the semiconductor device becomes more highly-integrated and miniaturized the LOCOS isolation method, which had been widely used previously for manufacturing the semiconductor device, has been replaced largely with a shallow trench isolation (STI) method because LOCOS method requires more space to implement than STI method. The STI method involves forming a trench and gap-filling the trench with an insulating layer to isolate the device.

In the STI method, a high density plasma (HDP) oxide layer is used commonly as the insulating layer for gap-filling the trench. However, as an aspect ratio of the trench is increased due to the high integration, gap-filling the trench with the HDP oxide layer has become difficult. If the aspect ratio of the trench is higher than 4, it becomes difficult to gap-fill the trench using the current HDP equipment. In a 60 nm NAND flash device, which is currently being developed, the aspect ratio of the isolation trench is approximately 5.5, which makes it difficult to gap-fill the trench using the HDP oxide layer.

### SUMMARY OF THE INVENTION

An embodiment of the present invention provides a method of forming an isolation structure of a semiconductor device which can enhance the gap-fill margin of an isolation trench.

In one embodiment, a method of forming an isolation structure of the semiconductor device comprises providing a semiconductor substrate on which an isolation trench is formed; forming a first insulating layer on an entire surface including the isolation trench; forming a spin on dielectric (SOD) insulating layer on an entire surface to fill the isolation trench with the SOD insulating layer; planarizing the SOD insulating layer to expose the semiconductor substrate; removing the SOD insulating layer by a certain thickness to expose an upper portion of the isolation trench; and forming a second insulating layer on an entire surface including the isolation trench.

In one embodiment, a method of forming an isolation structure of the semiconductor device comprises forming a tunnel oxide layer and a conductive layer for a floating gate on a semiconductor substrate; removing portions of the conductive layer, the tunnel oxide layer and the semiconductor substrate to form an isolation trench; forming a first high density plasma (HDP) oxide layer along a surface of an entire structure after forming the isolation trench; forming a spin on dielectric (SOD) insulating layer on an entire structure to fill the isolation trench with the SOD insulating layer after forming the HDP oxide layer; planarizing the SOD insulating layer to expose the conductive layer; removing a portion of the SOD insulating layer to form a recess; and forming a second HDP oxide layer on the entire structure including the recess.

In one embodiment, a method for forming an isolation structure of a semiconductor device includes forming an isolation trench on a semiconductor substrate. A first insulating layer is formed over the isolation trench and the substrate. A spin-on-dielectric (SOD) insulating layer is formed over the first insulation layer, the SOD insulating layer filling the isolation trench and extending above an upper level of the isolation trench. The SOD insulating layer provided within the isolation trench is removed to expose an upper portion of the isolation trench, wherein a lower portion of the isolation trench remains filled with the SOD insulating layer. A second insulating layer is formed over the SOD insulating layer that is filling the lower portion of the isolation trench, wherein the second insulating layer fills the upper portion of the isolation trench.

In another embodiment, a method for forming an isolation structure of a semiconductor device includes providing an isolation trench on a substrate, the isolation trench having a sidewall defined by the substrate, a tunneling dielectric layer provide over the substrate, and a conductive layer provided over the tunneling dielectric layer. A first high density plasma (HDP) oxide layer is formed over the substrate and within the isolation trench. A spin-on-dielectric (SOD) insulating layer is formed over the HDP oxide layer. The SOD insulating layer is planarized to provide the SOD insulating layer with a substantially planar upper surface. A portion of the SOD insulating layer provided within the isolation trench is removed to form a recess within the isolation trench and expose an upper portion of the isolation trench. A second HDP oxide layer is filled within the upper portion of the isolation trench to form an isolation structure within the isolation structure, the isolation structure including the SOD insulating layer and the second HDP oxide layer.

### BRIEF DESCRIPTION OF THE DRAWINGS

FIG. 1A to FIG. 1E are sectional views of a semiconductor device for illustrating a method of forming an isolation structure of a semiconductor device according to an embodiment of the present invention; and

FIG. 2 is a view illustrating a process of forming an insulating layer solidified through a molecular bonding structure of polysilazane (PSZ) and a heat treatment process.

### DESCRIPTION OF SPECIFIC THE INVENTION

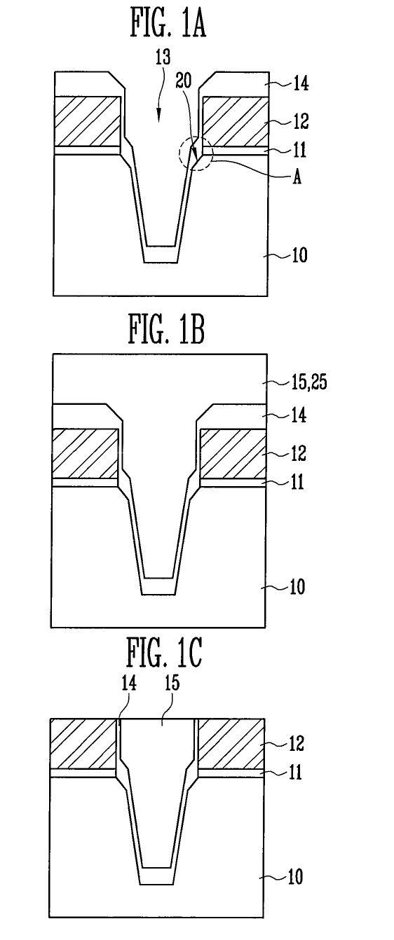

FIG. 1A to FIG. 1E are cross-sectional views of a semiconductor device for illustrating a method of forming an isolation structure of a semiconductor device according to an embodiment of the present invention. The drawings show a case where the embodiment of the present invention is applied to a self aligned shallow trench isolation (SA-STI) scheme.

As shown in FIG. 1A, a tunnel oxide layer 11 and a polysilicon layer 12 for a floating gate are formed sequentially on a semiconductor substrate 10, the polysilicon layer 12 for the floating gate, the tunnel oxide layer 11 and the semiconductor substrate 10 are etched to a certain depth through a photolithography process to form an isolation trench 13. Then, a first insulating layer 14 is formed on a surface including the isolation trench 13. It is preferable to form a high density plasma (HDP) oxide layer having a thickness of 100 to 2,000 angstrom (□) as the first insulating layer 14. The first insulating layer 14 is deposited thinly within the isolation trench 13.

As indicated by FIG. 1A, however, the first insulating layer 14 formed on the side surface of the tunnel oxide layer 11 has a thickness which is thicker than that of the first insulating layer 14 formed on other regions (see region “A”). This results due to a sloping step 20 formed below the tunnel oxide layer 11. The slope of the sloping step 20 is less than that of the other sidewalls of the isolation trench 13, thereby the first insulation layer 14 is more easily deposited thereon.

The sloping step 20 is formed using CF₄+CHF₃ Gas Mixture, which can make polymer around floating gate like a spacer (Polymer spacer). This spacer can make slope profile during trench etch step.

Referring to FIG. 1B, a layer 25 having polysilazane (PSZ) is deposited over first insulating layer 14 and fills the isolation trench 13. The layer 25 has fluidity. The layer 25 is deposited using a spin-on-dielectric (SOD) method. When a SOD method is used deposit the layer 25 having PSZ material (or PSZ layer 25) a trench having a high aspect ratio may be filled without voids since the PSZ material has low viscosity, which allows the material to flow more easily than the conventional HDP oxide. The thickness of the PSZ layer 25 on the first insulation layer 14 (away from the isolation trench 13) is between 1,000 to 8,000 angstroms (Å). A wet heat treatment process is performed in an atmosphere of H₂O and O₂ gas and a temperature of 300 to 1,200□ to solidify the PSZ layer 25 and form a SOD insulating layer 15. The SOD insulating layer 15 includes silicon oxide (SiO₂) in the present embodiment. The heat treating process generates the gas by-products NH₃ and H₂ which are exhausted.

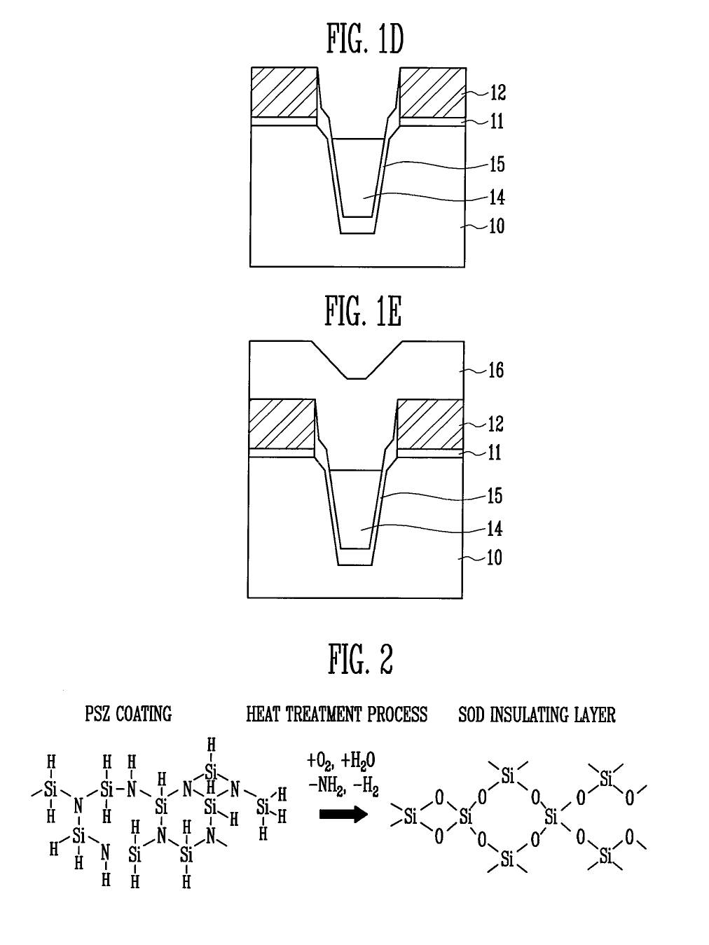

Referring to FIG. 2, the PSZ substance consists essentially of silicon (Si), hydrogen (H) and nitrogen (N) when first deposited on the first insulating layer 14 via a SOD method. The PSZ substance has SixHyNz (here, ‘x’, ‘y’ and ‘z’ are variable). When the PSZ substance is heat-treated under an atmosphere of H₂O and O₂ gas, the SOD insulating layer 15 consisting essentially of silicon oxide (SiO₂) is formed. And, NH₃ and H₂ are generated as the by-product, these gaseous elements are exhausted.

Although the gap filling characteristic of the SOD insulating layer 15 is superior than that of the HDP oxide layer, the etch rate of the SOD insulating layer against wet etchant is high. Accordingly, if the SOD insulating layer is exposed to wet etchant utilized in a subsequent process, the SOD insulating layer is rapidly lost. Accordingly, there is need to protect the SOD insulating layer 15 from a subsequent process. In the present embodiment, a protective layer 16 (see FIG. 1E) is formed over the SOD layer 15 after removing an upper portion of the SOD layer 15.

Although not shown, as compared with a central portion of the cell area, the edge of the cell area and the periphery circuit area are coated more thinly with the PSZ material. That is, the PSZ layer 25 has a greater thickness at the middle than at the edge due to the SOD method. The SOD insulating layer 15 derived from the heat-treating the PSZ layer 25, accordingly, has the same profile as that of the PSZ layer 25. In this state, once an etching process is carried out for reducing the thickness of the SOD insulating layer 15, the edge portion of the cell area and the periphery circuit area would be etched to a height which is lower than that of the central portion of the cell area. Due to the above conditions, the gap fill margin may be reduced when an insulating layer is formed on the SOD layer 15. Effective field height (EFH) in cell edge area is lower than in cell central area. So, the effective height for gap fill with followed HDP deposition is higher in cell edge area than in cell central area. That is, HDP gap fill is more difficult in cell edge area than in cell central area. The variation in effective field height may be increased.

In addition, as shown in FIG. 1C, a planarizing process for the SOD insulating layer 15 is carried out to remove the first insulating layer 14 and the SOD insulating layer 15 formed outside the isolation trench 13.

A chemical mechanical polishing (CMP) process is utilized as the planarizing process, and a slurry (HSS) having a high selection ratio between the oxide layer and the polysilicon layer is used. If the HSS is used as described above, the CMP process may be halted more easily when the polysilicon layer 12 is exposed without removing much of the polysilicon layer 12.

Subsequently, as shown in FIG. 1D, the SOD insulating layer 15 is etched by 300 to 2,000 angstrom (Å) by utilizing wet etchant to expose the upper portion of the isolation trench 13. Buffer oxide etchant (BOE) or HF is used as the wet etchant.

At this time, if the tunnel oxide layer 11 is etched by the wet etchant, voids are generated when a subsequent filling process using the insulating layer is performed since the insulating layer may not be able to completely fill the etched portion of the tunnel oxide, which extends laterally. However, since the first insulating layer 14 is formed thickly on the side surface of the tunnel oxide layer 11, when the process for etching the SOD insulating layer 15 is carried out, the tunnel oxide layer 11 is not exposed and protected by the first insulating layer 14, thereby preventing generation of voids.

Subsequently, as shown in FIG. 1E, a second insulating layer 16 (or protective layer) is formed on a surface including the isolation trench 13. A HDP oxide layer with a thickness of 1,000˜6,000□ is formed as the second oxide layer 16. Since the isolation trench 13 is already partially filled with the SOD insulating layer 15, the second insulating layer 15 only has a relatively shallow depth to fill the isolation trench 13. Accordingly, the gap fill margin of the isolation trench 13 is sufficient.

Subsequently, although not illustrated, a planarizing process for the second insulating layer 16 is carried out to expose the polysilicon layer 12 and form an isolation structure.

The above description regarding the embodiment illustrates the case where the present invention is applied to the SA-STI scheme in which the tunnel oxide layer 11 and the polysilicon layer 12 for the floating gate are formed on the semiconductor substrate and the isolation trench 13 is then formed and filled with an insulating layer to form the isolation structure. However, the present invention is not limited thereto, but can be applied to other manufacturing methods for a semiconductor device in which the trench is formed and then filled with the insulating layer to form the isolation structure.

The embodiments of the present invention as described above have one or more of the following advantages as follows.

First, it is possible to prevent voids from forming in the isolation structure which can have a bad effect on the device characteristics and so device failure can be reduced and the yield of the device can be increased.

Second, although future devices are continuously miniaturized, there is no need for new equipment when an acceptable isolation structure can be formed by utilizing conventional equipment, and so equipment cost can be saved.

Third, since the SOD insulating layer is not exposed in the subsequent process, a loss of the SOD insulating layer is prevented, and so the isolation characteristic can be secured.

Fourth, it is possible to protect the tunnel oxide layer by forming the first insulating layer with a large enough thickness on the side surface of the tunnel oxide layer. Accordingly, the generation of voids can be prevented.

Fifth, since the SOD insulating layer can be formed such that the SOD insulating layer has the uniform thickness by performing the chemical mechanical polishing process after forming the SOD insulating layer, the gap fill margin of the insulating layer formed in the subsequent process can be enhanced and a variation of the effective field height (EFH) can be reduced.

Although the present invention has been described in connection with the specific embodiments, the scope of the present invention is not limited by the specific embodiments but should be construed by the appended claims. Further, it should be understood by those skilled in the art that various changes and modifications can be made without departing from the spirit and scope of the present invention.

What is claimed is:

1. A method of forming an isolation structure of a semiconductor device, the method comprising:
forming an isolation trench on a semiconductor substrate;
forming a first insulating layer over the isolation trench and the substrate;
forming a spin-on-dielectric (SOD) insulating layer over the first insulation layer, the SOD insulating layer filling the isolation trench and extending above an upper level of the isolation trench;
removing the SOD insulating layer provided within the isolation trench to expose an upper portion of the isolation trench, wherein a lower portion of the isolation trench remains filled with the SOD insulating layer; and
forming a second insulating layer over the SOD insulating layer filling the lower portion of the isolation trench, wherein the second insulating layer fills the upper portion of the isolation trench.

2. The method of forming the isolation structure of the semiconductor device as claimed in claim 1, wherein the second insulating layer is formed of a high density plasma (HDP) oxide layer.

3. The method of claim 1, further comprising:
smoothing the SOD insulating layer, so that an upper surface of the SOD layer is substantially flushed to the upper level of the isolation trench prior to the removing step.

4. The method as claimed in claim 1, wherein the first insulating layer has a thickness of 100˜2000Å

5. The method as claimed in claim 1, wherein forming the SOD insulating layer comprises:
forming a layer including polysilazane (PSZ) via a SOD method; and
thereafter, heating the PSZ layer.

6. The method as claimed in claim 5, wherein the PSZ layer has a thickness of 1,000˜8,000Å

7. The method as claimed in claim 5, wherein the heat treatment is performed under the conditions of an atmosphere including H₂O or O₂, or both, at a temperature of 300˜1,200° C.

8. The method as claimed in claim 1, wherein the removing step involves a wet etching process.

9. The method as claimed in claim 1, wherein the SOD insulating layer to be removed has a thickness of 300˜2,000Å

10. The method as claimed in claim 1, wherein the second insulating layer has a thickness of 1,000˜6,000Å.

11. The method as claimed in claim 1, wherein the isolation trench has a sloping step configured to support the first insulating layer.

12. A method for forming an isolation structure of a semiconductor device, the method comprising:
providing an isolation trench on a substrate, the isolation trench having a sidewall defined by the substrate, a tunneling dielectric layer provide over the substrate, and a conductive layer provided over the tunneling dielectric layer;
forming a first high density plasma (HDP) oxide layer over the substrate and within the isolation trench;
forming a spin-on-dielectric (SOD) insulating layer over the HDP oxide layer;
planarizing the SOD insulating layer to provide the SOD insulating layer with a substantially planar upper surface;
removing a portion of the SOD insulating layer provided within the isolation trench to form a recess within the isolation trench and expose an upper portion of the isolation trench; and
filling a second HDP oxide layer within the upper portion of the isolation trench to form an isolation structure within the isolation structure, the isolation structure including the SOD insulating layer and the second HDP oxide layer.

13. The method as claimed in claim 12, wherein forming the SOD insulating layer including coating a polysilazane (PSZ) layer over the isolation trench and heat-treating the PSZ layer.

14. The method as claimed in claim 13, wherein the heat treatment is performed in an atmosphere including H₂O or O₂ gas, or both.

15. The method as claimed in claim 12, wherein the recess is formed using wet etchant.

16. The method as claimed in claim 15, wherein the wet etchant comprises at least buffer oxide etchant (BOE) or HF.

17. The method as claimed in claim 12, wherein the SOD insulating layer is planarized using a chemical mechanical polishing (CMP) process.

18. The method as claimed in claim 17, wherein the chemical mechanical polishing (CMP) process utilizes a slurry having a selection ratio between oxide and silicon.

19. The method as claimed in claim 12, wherein the isolation trench has a sloping step configured to support the first HDP oxide layer.

20. The method as claimed in claim 19, wherein the sloping step is provided proximate to the tunneling dielectric layer to protect the tunneling dielectric layer from a subsequent etch process.
